(19) United States
(12) Patent Application Publication
(10) Pub. No.: US 2025/0143028 A1
(43) Pub. Date: May 1, 2025

(54) LIGHT-EMITTING DIODE DEVICE AND WAFER STRUCTURE

(71) Applicant: Quanzhou sanan semiconductor technology Co., Ltd., Fujian (CN)

(72) Inventors: Jun Wang, Fujian (CN); Kunta HSIEH, Fujian (CN); Tao HAN, Fujian (CN); Hongyi ZHOU, Fujian (CN)

(73) Assignee: Quanzhou sanan semiconductor technology Co., Ltd., Fujian (CN)

(21) Appl. No.: 18/924,901

(22) Filed: Oct. 23, 2024

(30) Foreign Application Priority Data
Oct. 30, 2023 (CN) 202311416656.7

(51) Int. Cl. H01L 33/44; H01L 27/15; H01L 33/10; H01L 33/14; H01L 33/38; H01L 33/42

(52) U.S. Cl. CPC H10H 20/84; H10H 20/814; H10H 20/816; H10H 20/8316; H10H 20/833; H10H 29/142

(57) ABSTRACT

A light-emitting diode device including a substrate, a structural layer, and a light-emitting diode mesa is provided. The substrate has a first surface and a second surface arranged opposite each other. The first surface includes a first region and a second region, and the second region surrounds the first region. The structural layer covers the first region and the second region and at least includes an electrode layer, a second insulating layer, and a first insulating layer stacked in sequence from the first surface. The light-emitting diode mesa is arranged above the first region of the structural layer and includes a semiconductor epitaxial layer. The semiconductor epitaxial layer includes a second semiconductor layer, an active layer, and a first semiconductor layer stacked in sequence from the first surface.

### CROSS-REFERENCE TO RELATED APPLICATION

This application claims the priority benefit of China application serial no. 202311416656.7, filed on Oct. 30, 2023. The entirety of the above-mentioned patent application is hereby incorporated by reference herein and made a part of this specification.

### BACKGROUND

### Technical Field

The disclosure relates to the technical field related to light-emitting diodes, and in particular, relates to a light-emitting diode device and a wafer structure.

### Description of Related Art

Light-emitting diode devices feature advantages such as long service life, high luminous efficiency, no radiation, and low power consumption, and are widely applied in fields such as lighting, indicator lights, and automotive lights.

In the process of manufacturing light-emitting diode devices, laser is usually required to cut the wafer. In existing small-sized vertical light-emitting diode devices, an epitaxial layer is usually arranged on the cutting path. During cutting, the laser needs to split the epitaxial layer, but the forward scribing and back scribing are prone to cause scribing deviation of a cutting path, so cutting path cracking occurs easily. This results in a poor appearance of the light-emitting diode devices, and the quality of the light-emitting diode devices is also affected.

In order to decrease the appearance defect of light-emitting diode devices and increase the quality of light-emitting diode devices, the disclosure provides a light-emitting diode device and a wafer structure.

### SUMMARY

The disclosure provides a light-emitting diode device and a wafer structure for solving the problem that in an existing light-emitting diode device, laser needs to split the epitaxial layer, and the forward scribing and back scribing are prone to cause scribing deviation of a cutting path, resulting in unfavorable appearance and decreased product quality.

An embodiment of the disclosure provides a light-emitting diode device including a substrate, a structural layer, and a light-emitting diode mesa.

The substrate has a first surface and a second surface arranged opposite to each other, the first surface includes a first region and a second region, and the second region surrounds the first region.

The structural layer covers the first region and the second region and at least includes an electrode layer, a second insulating layer, and a first insulating layer stacked in sequence from the first surface.

The light-emitting diode mesa is arranged above the first region of the structural layer and includes a semiconductor epitaxial layer including a second semiconductor layer, an active layer, and a first semiconductor layer stacked in sequence from the first surface.

Another embodiment of the disclosure further provides a wafer structure including a plurality of light-emitting diode devices of the disclosure arranged in sequence. Edges of the second regions of adjacent light-emitting diode devices are connected to each other to form a cutting path.

As described above, the light-emitting diode device and the wafer structure provided by the disclosure exhibit the following beneficial effects.

In the light-emitting diode device provided by the disclosure, the structural layer covers the second region. Since the first insulating layer and the second insulating layer in the structural layer are transparent dielectric layers and the refractive index of a transparent dielectric layer is lower than that of an epitaxial layer, when laser cuts the wafer to form the light-emitting diode device, the laser can easily penetrate and scribe, so the cutting difficulty is lowered. In this way, the scribing deviation is reduced, the cracking and damaging are decreased, the appearance yield of the light-emitting diode device formed by cutting is effectively improved, and the quality of the light-emitting diode device is enhanced.

### BRIEF DESCRIPTION OF THE DRAWINGS

FIG. 1 is a schematic top view of a structure of a light-emitting diode device according to Embodiment 1 of the disclosure.

FIG. 2 is a schematic cross-sectional view of the structure taken alone a cross-sectional line A-A in FIG. 1.

FIG. 3 to FIG. 13 are schematic cross-sectional views of a manufacturing process of the light-emitting diode device according to Embodiment 1.

FIG. 14 is a schematic top view of a structure of a light-emitting diode device according to Embodiment 2 of the disclosure.

FIG. 15 is a schematic cross-sectional view of the structure taken alone a cross-sectional line B-B in FIG. 14.

FIG. 16 is a schematic top view of a structure of a light-emitting diode device according to Embodiment 3 of the disclosure.

FIG. 17 is a schematic cross-sectional view of the structure taken alone a cross-sectional line C-C in FIG. 16.

FIG. 18 and FIG. 19 are schematic cross-sectional views of part of a manufacturing process of a light-emitting diode device according to Embodiment 3.

FIG. 20 is a schematic top view of a structure of a wafer structure according to Embodiment 4 of the disclosure.

FIG. 21 is a schematic top view of a structure of a wafer structure according to Embodiment 5 of the disclosure.

FIG. 22 is a schematic top view of a structure of a wafer structure according to Embodiment 6 of the disclosure.

### DESCRIPTION OF REFERENCE NUMERALS OF THE ELEMENTS

100: growth substrate; 200: semiconductor epitaxial layer; 201: light-emitting diode mesa; 210: first semiconductor layer; 220: active layer; 230: second semiconductor layer; 240: trench; 241: conductive pillar; 300: structural layer; 310: first insulating layer; 311: through hole; 312: discontinuous region; 313: metal blocking wall region; 320: second insulating layer; 330: electrode layer; 340: transparent conductive layer; 350: reflective metal layer; 360: current spreading layer; 370: metal blocking wall; 400: bonding layer; 500: substrate; 510: first region; 520: second region; 521: edge region; 522: electrode region; 523: middle region; 600: first electrode; 700: second electrode; 800: third insulating layer; 900: cutting path.

### DESCRIPTION OF THE EMBODIMENTS

The implementation of the disclosure is illustrated below by specific embodiments. A person having ordinary skill in the art can easily understand other advantages and effects of the disclosure from the content disclosed in this specification. The disclosure can also be implemented or applied through other different specific implementation ways. The details in this specification can also be modified or changed based on different viewpoints and applications without departing from the spirit of the disclosure.

The disclosure provides a light-emitting diode device including a substrate, a structural layer, and a light-emitting diode mesa.

The substrate has a first surface and a second surface arranged opposite to each other, the first surface includes a first region and a second region, and the second region surrounds the first region.

The structural layer covers the first region and the second region and at least includes an electrode layer, a second insulating layer, and a first insulating layer stacked in sequence from the first surface.

The light-emitting diode mesa is arranged above the structural layer, corresponds to the first region, and includes a semiconductor epitaxial layer including a second semiconductor layer, an active layer, and a first semiconductor layer stacked in sequence from the first surface.

In the light-emitting diode device provided in this embodiment, the first insulating layer and the second insulating layer of the structural layer are arranged in the second region. Since the first insulating layer and the second insulating layer are transparent dielectric layers and a refractive index of a transparent dielectric layer is lower than that of an epitaxial layer, when laser cuts the wafer to form the light-emitting diode device, the laser can easily penetrate and scribe, so the cutting difficulty is lowered. In this way, the scribing deviation can be reduced, the cracking and damaging are decreased, the appearance yield of the light-emitting diode device formed by cutting is effectively improved, and the quality of the light-emitting diode device is enhanced.

In some embodiments, the second region includes an edge region away from the first region, and a thickness of the first insulating layer located in the edge region is between 0.1 μm and 1.4 μm.

In some embodiments, a total thickness of the first insulating layer and the second insulating layer located in the edge region is between 0.4 μm and 5 μm.

The total thickness of the first insulating layer and the second insulating layer in the edge region of the second region is thinner than the thickness of the epitaxial layer, which further reduces the difficulty of cutting. Laser scribing can be easily performed, which further improves the appearance yield of the light-emitting diode device formed by cutting and further improves the quality of the light-emitting diode device.

In some embodiments, the second region further includes an electrode region located between the edge region and the first region. The first insulating layer located in the electrode region has a discontinuous region, and a first electrode is arranged in the discontinuous region.

In some embodiments, the second region further includes a middle region located between the edge region and the electrode region, and a thickness of the first insulating layer located in the edge region is less than a thickness of the first insulating layer located in the middle region. Reducing the thickness of the first insulating layer in the edge region of the second region is beneficial to further reducing the total thickness of the first insulating layer and the second insulating layer in the edge region, and the cutting difficulty is further reduced. Laser is easier to scribe, which prevents the first insulating layer from breaking during scratching, so the appearance yield of the light-emitting diode device formed by cutting is further improved, and the quality of the light-emitting diode device is further enhanced.

In some embodiments, the structural layer located in the edge region at least includes the electrode layer and the second insulating layer stacked in sequence from the first surface, and a metal blocking wall is arranged above the second insulating layer. By replacing the first insulating layer in the edge region with the metal blocking wall, laser cutting of the wafer is less difficult than cutting epitaxy. The metal blocking wall facilitates laser transmission and can effectively prevent the second insulating layer from being cut and cracked. Further, the metal blocking wall also exhibits the function of blocking slag, so that the appearance yield of the light-emitting diode device formed by cutting is further improved, and the quality of the light-emitting diode device is further enhanced.

In some embodiments, a height of the metal blocking wall is between 1 μm and 2 μm.

In some embodiments, a width of the first electrode is less than a width of the discontinuous region.

In some embodiments, the width of the discontinuous region is between 2 μm and 4 μm.

In some embodiments, a current spreading layer is arranged between the first insulating layer and the second insulating layer and extends from the first region to the electrode region, and the first electrode is connected to the current spreading layer. The current spreading layer is used to spread a current, so that the current distribution is more uniform, an operating voltage of the light-emitting diode device is reduced, and the light output effect of the light-emitting diode device is improved.

In some embodiments, a thickness of the current spreading layer is between 0.3 μm and 1 μm.

In some embodiments, a third insulating layer is arranged above a surface and a sidewall of the light-emitting diode mesa and the structural layer in the second region except the discontinuous region.

In some embodiments, a third insulating layer is arranged above a surface and a sidewall of the light-emitting diode mesa and the structural layer in the second region except the discontinuous region and the edge region.

In some embodiments, a third insulating layer is arranged above a surface and a sidewall of the light-emitting diode mesa, a sidewall close to the light-emitting diode mesa and a surface of the metal blocking wall, and the structural layer in the electrode region except the discontinuous region.

The third insulating layer has the property of allowing most of the light to pass through and achieving insulating protection for the light-emitting diode device.

In some embodiments, the first insulating layer, the second insulating layer, and the third insulating layer are all transparent insulating layers.

In some embodiments, in a region corresponding to the light-emitting diode mesa, a through hole is arranged in the first insulating layer, and a reflective metal layer is arranged between the first insulating layer and the current spreading layer. The reflective metal layer covers the first insulating layer at the light-emitting diode mesa and fills the through hole to be electrically connected to the second semiconductor layer.

A transparent conductive layer is further arranged between the first insulating layer and the second semiconductor layer at the light-emitting diode mesa.

The through hole formed in the first insulating layer facilitates electrical conduction. The reflective metal layer can reflect the light radiated from the semiconductor epitaxial layer toward the first surface side of the substrate, so that the overall light output effect of the light-emitting diode device is improved. The reflective metal layer is embedded in the through hole formed by the first insulating layer, forms an ODR reflective structure with the transparent conductive layer, and reflects the light radiated from the semiconductor epitaxial layer toward the first surface side and radiates it from a light output side, so that the light output efficiency of the light-emitting diode device is improved.

In some embodiments, the light-emitting diode mesa further includes a conductive pillar arranged on the semiconductor epitaxial layer, and the conductive pillar penetrates the second semiconductor layer, the active layer, and a portion of the first semiconductor layer. A sidewall of the conductive pillar is the first insulating layer and the second insulating layer arranged in sequence, and the electrode layer is formed on a sidewall of the second insulating layer and the first semiconductor layer to be electrically connected to the first semiconductor layer.

In some embodiments, a surface of the first semiconductor layer away from the active layer is a rough surface.

The rough surface is beneficial to improving the light output effect.

In some embodiments, a bonding layer is further arranged between the structural layer and the substrate.

A second electrode is arranged on the second surface.

The bonding layer bonds the structural layer to the substrate.

Another embodiment of the disclosure further provides a wafer structure including a plurality of light-emitting diode devices provided by the disclosure arranged in sequence. Edges of the second regions of adjacent light-emitting diode devices are connected to each other to form a cutting path.

Compared with arranging an epitaxial layer on the cutting path, in the wafer structure provided by this embodiment, the structural layer covers the cutting path, so the cutting difficulty is reduced. The cracking and damaging of the cutting path during laser cutting are effectively prevented, the appearance yield of the light-emitting diode device formed by cutting is effectively improved, and the quality of the light-emitting diode device is enhanced.

In the related art, especially in small-sized vertical light-emitting diode devices, epitaxial layers are usually arranged at the cutting paths. During the manufacturing process, the laser needs to split the epitaxy, but the forward scribing and back scribing are prone to cause scribing deviation of a cutting path, so cutting path cracking occurs easily. As a result, the appearance of the light-emitting diode device formed by cutting is unfavorable and the quality of the light-emitting diode device is affected.

In view of the above defects, the disclosure provides a light-emitting diode device and a wafer structure, which are described in detail through the following embodiments.

### Embodiment 1

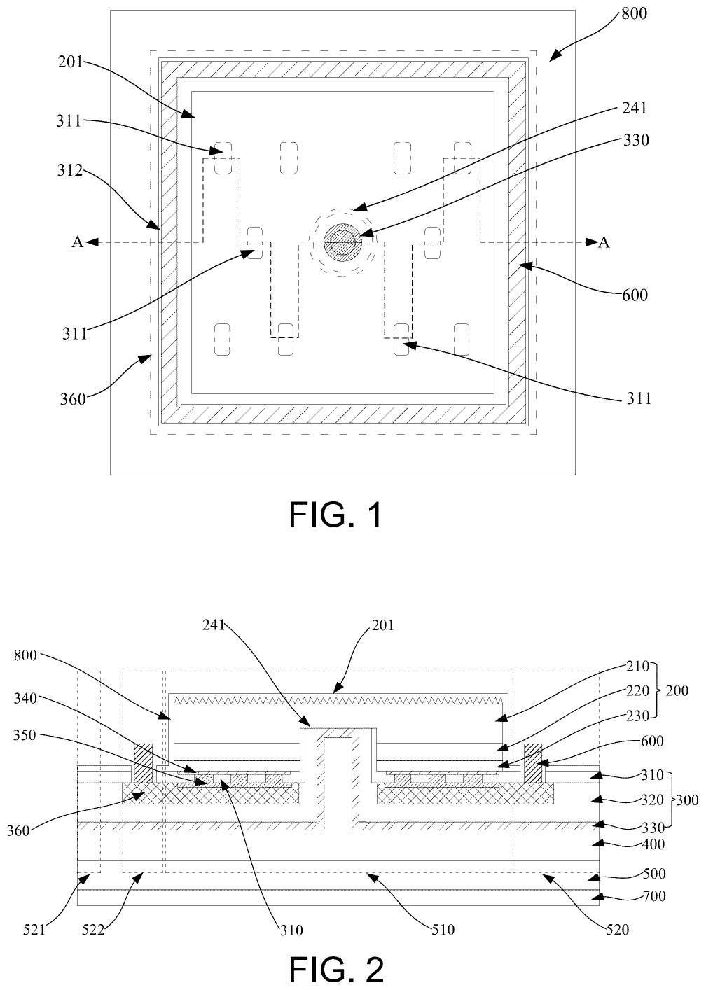

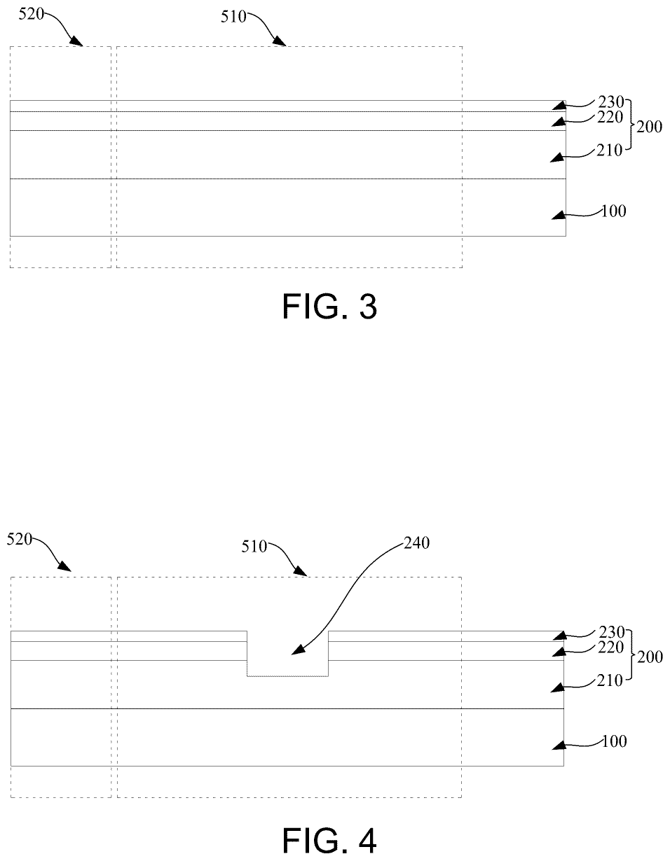

This embodiment provides a light-emitting diode device. With reference to FIG. 1 and FIG. 2, the light-emitting diode device includes a substrate 500, a structural layer 300, and a light-emitting diode mesa 201. The substrate 500 has a first surface and a second surface that are arranged opposite to each other (in FIG. 2, an upper surface of the substrate 500 is a first surface, and a lower surface of the substrate 500 is a second surface). The first surface includes a first region 510 and a second region 520, and the second region 520 surrounds the first region 510.

The structural layer 300 covers the first region 510 and the second region 520. The structural layer 300 includes at least an electrode layer 330, a second insulating layer 320, and a first insulating layer 310 stacked in sequence from the first surface (in FIG. 2, from bottom to top, the structural layer 300 includes at least the electrode layer 330, the second insulating layer 320, and the first insulating layer 310 arranged in sequence). The first insulating layer 310 and the second insulating layer 320 are formed by a chemical vapor deposition method. The light-emitting diode mesa 201 is arranged above the structural layer 300, corresponds to the first region 510, and includes a semiconductor epitaxial layer 200 including a second semiconductor layer 230, an active layer 220, and a first semiconductor layer 210 stacked in sequence from the first surface (in FIG. 2, from bottom to top, the semiconductor epitaxial layer 200 includes a second semiconductor layer 230, an active layer 220, and a first semiconductor layer 210 stacked in sequence).

It can be understood that the first region 510 and the second region 520 are three-dimensional space regions and may extend in a direction perpendicular to the first surface of the substrate 500.

In the light-emitting diode device of this embodiment, the structural layer 300 extends to an edge of the second region 520. Since the first insulating layer 310 and the second insulating layer 320 of the structural layer 300 are transparent dielectric layers and the refractive index of a transparent dielectric layer is lower than that of an epitaxial layer, when laser cuts the wafer to form the light-emitting diode device, the laser can easily penetrate and scribe, so the cutting difficulty is lowered. In this way, the scribing deviation can be reduced, the cracking and damaging are decreased, the appearance yield of the light-emitting diode device formed by cutting is effectively improved, and the quality of the light-emitting diode device is enhanced.

The substrate 500 provides mechanical support for the structural layer 300 and the light-emitting diode mesa 201. Further, the substrate 500 is a conductive substrate, and a material of the conductive substrate may be, for example, silicon, silicon carbide, or metal. The metal may be, for example, copper, tungsten, molybdenum, or an alloy of the aforementioned metal materials.

The first insulating layer 310 and the second insulating layer 320 are formed by chemical vapor deposition (CVD). The edge of the second region 520 is covered, so that when laser scribes a wafer, the laser can easily penetrate and scribe the wafer, which reduces the difficulty of cutting, reduces the scribing deviation, and lowers cracking and damaging. The first region 510 is covered, so that different electrodes in the light-emitting diode device can be blocked. A material of the first insulating layer 310 and the second insulating layer 320 is a transparent insulating material, which may be, for example, one of SiO₂, SiN, SiOx Ny, TiO₂, Si₃N₄, Al₂O₃, TIN, AlN, ZrO₂, TiAlN, TiSiN, HfO₂, TaO₂, MgF₂, or a Bragg reflector (DBR) formed by repeatedly stacking two or more of the aforementioned materials. In an optional embodiment, the first insulating layer 310 located in different regions has different functions. The first insulating layer 310 located in the first region 510 may be an insulating reflective layer for reflecting light and blocking different electrodes in the light-emitting diode device, so that the light-emitting diode device has improved light extraction efficiency. The first insulating layer 310 may be a multi-layer film structure formed by alternately stacking different high-refractive-index dielectric films and different low-refractive-index dielectric films. A material of the high-refractive-index dielectric films may be, for example, TiO₂, NB₂O₅, TA₂O₅, HfO₂, ZrO₂, etc. A material of the low-refractive-index dielectric films may be, for example, SiO₂, MgF₂, Al₂O₅, SiON, etc. Since the first insulating layer 310 located in the second region 520 is a transparent insulating layer, when cutting the first insulating layer 310 located at the edge, the laser can easily penetrate and scribe it, the cutting difficulty is reduced, the scribing deviation is lowered, and the cracking and damaging are decreased. The second insulating layer 320 located in the second region 520 also has the function of protecting an internal structure of the light-emitting diode device.

The first semiconductor layer 210 is an N-type semiconductor layer that provides electrons through N-type doping, and the N-type semiconductor layer may be formed by doping a semiconductor with Si, Ge, Sn, Se, Te, etc., for example. The second semiconductor layer 230 is a P-type semiconductor layer that provides electron holes through P-type doping, and the P-type semiconductor layer may be formed by doping a semiconductor with Mg, Zn, Ca, Sr, Ba, etc., for example. The active layer 220 provides radiation for the recombination of electrons and electron holes, and the active layer 220 is a multi-quantum well layer.

The electrode layer 330 is made of metal and is used to be electrically connected to the first semiconductor layer 210. The electrode layer 330 may be an N-type electrode layer. A material of the electrode layer 330 may be, for example, Al, Ag, Cr, Pt, TiW, etc.

In an optional embodiment, the second region 520 includes an edge region 521 away from the first region 510, and a thickness of the first insulating layer 310 in the edge region 521 is between 0.1 μm and 1.4 μm. To be specific, the thickness of the first insulating layer 310 located in the edge region 521 may be, for example, 0.1 μm, 0.2 μm, 0.3 μm, 0.4 μm, 0.5 μm, 0.6 μm, 0.7 μm, 0.8 μm, 0.9 μm, 1.0 μm, 1.1 μm, 1.2 μm, 1.3 μm, 1.4 μm, etc. Optionally, a total thickness of the first insulating layer 310 and the second insulating layer 320 located in the edge region 521 is between 0.4 μm and 5 μm. To be specific, the total thickness of the first insulating layer 310 and the second insulating layer 320 located in the edge region 521 may be, for example, 0.4 μm, 0.5 μm, 0.6 μm, 0.7 μm, 0.8 μm, 0.9 μm, 1.0 μm, 1.5 μm, 2.0 μm, 2.5 μm, 3 μm, 3.5 μm, 4 μm, 4.5 μm, 5 μm, etc. The total thickness of the first insulating layer 310 and the second insulating layer 320 located in the edge region 521 is thinner than the thickness of the epitaxial layer. Compared with cutting the epitaxial layer, in this embodiment, by cutting the first insulating layer 310 and the second insulating layer 320, the laser can easily penetrate and scribe, so cutting difficulty is lowered, the scribing deviation is reduced, and the cracking and damaging are decreased. The appearance yield of the light-emitting diode device formed by cutting is further improved, and the product quality of the light-emitting diode device is enhanced.

In an optional embodiment, the second region 520 further includes an electrode region 522 located between the edge region 521 and the first region 510. The first insulating layer 310 located in the electrode region 522 has a discontinuous region 312, and a first electrode 600 is arranged in the discontinuous region 312. The first electrode 600 may be a P-type electrode. A material of the first electrode 600 may be, for example, Ti, Pt, Ni, Au, etc.

In an optional embodiment, a width of the first electrode 600 is less than a width of the discontinuous region 312. The first electrode 600 may be manufactured by a coating method such as electron beam evaporation. The width of the discontinuous region 312 is set to be greater than the width of the first electrode 600, so that a side plating space of the first electrode 600 may be reserved, thereby facilitating side plating of the first electrode 600. Optionally, the width of the discontinuous region 312 is between 2 μm and 4 μm. Optionally, the width of the discontinuous region 312 may be, for example, 2 μm, 2.5 μm, 3 μm, 3.5 μm, 4 μm, etc.

In an optional embodiment, a current spreading layer 360 is arranged between the first insulating layer 310 and the second insulating layer 320 and extends from the first region 510 to the electrode region 522, and the first electrode 600 is connected to the current spreading layer 360. The current spreading layer 360 is used to spread the current, so that the current distribution is more uniform, the operating voltage of the light-emitting diode device is reduced, and the light output effect of the light-emitting diode device is improved. The current spreading layer 360 may be made of a metal material or a transparent conductive material. The metal material may be, for example, Au, Zn, Be, Ti, Pt, or an alloy of the aforementioned materials. The transparent conductive material may be, for example, indium tin oxide (ITO), indium zinc oxide (IZO), indium oxide (InO), tin oxide (SnO), cadmium tin oxide (CTO), antimony tin oxide (ATO), aluminum zinc oxide (AZO), zinc tin oxide (ZTO), zinc oxide doped with gallium (GZO), indium oxide doped with tungsten (IWO), or zinc oxide (ZnO), etc. Optionally, a thickness of the current spreading layer 360 is between 0.3 μm and 1 μm. To be specific, the thickness of the current spreading layer 360 may be, for example, 0.3 μm, 0.4 μm, 0.5 μm, 0.6 μm, 0.7 μm, 0.8 μm, 0.9 μm, 1 μm, etc.

In an optional embodiment, in the region corresponding to the light-emitting diode mesa 201, that is, the first region 510, a through hole 311 is arranged in the first insulating layer 310, and a reflective metal layer 350 is arranged between the first insulating layer 310 and the current spreading layer 360. The reflective metal layer 350 covers the first insulating layer 310 at the light-emitting diode mesa 201 and fills the through hole 311, so that the reflective metal layer 350 is electrically connected to the second semiconductor layer 230. The through hole 311 facilitates electrical conduction. The reflective metal layer 350 can reflect the light radiated from the semiconductor epitaxial layer 200 toward the first surface of the substrate 500, so that the light returns to the semiconductor epitaxial layer 200 and radiates out from the light output side, and that the overall light output effect of the light-emitting diode device is improved.

In an optional embodiment, a transparent conductive layer 340 is further arranged between the first insulating layer 310 and the second semiconductor layer 230 at the light-emitting diode mesa 201. The reflective metal layer 350 is embedded in the through hole 311 formed by the first insulating layer 310, forms an ODR reflective structure with the transparent conductive layer 340, and reflects the light radiated from the semiconductor epitaxial layer 200 toward the first surface side, returns the light to the semiconductor epitaxial layer 200, and radiates it from the light output side, so that the light output efficiency of the light-emitting diode device is improved. The transparent conductive layer 340 may be an ohmic contact layer and forms an ohmic contact with the second semiconductor layer 230. A material of the transparent conductive layer 340 may be, for example, an alloy material such as ITO, IZO, AuZn, AuGe, NiAu, AuGeNi or AuBe. The first electrode 600 is electrically connected to the second semiconductor layer 230 through the current spreading layer 360, the reflective metal layer 350, and the transparent conductive layer 340.

In an optional embodiment, the light-emitting diode mesa 201 further includes a conductive pillar 241 arranged on the semiconductor epitaxial layer 200, and the conductive pillar 241 penetrates the second semiconductor layer 230, the active layer 220, and a portion of the first semiconductor layer 210. A sidewall of the conductive pillar 241 is the first insulating layer 310 and the second insulating layer 320 arranged in sequence, and the electrode layer 330 is formed on a sidewall of the second insulating layer 320 and the first semiconductor layer 210, so that the electrode layer 330 can be electrically connected to the first semiconductor layer 210.

In an optional embodiment, the surface of the first semiconductor layer 210 away from the active layer 220 is a rough surface, and the rough surface is beneficial to the light output effect of the light-emitting diode device.

In an optional embodiment, a bonding layer 400 is further arranged between the structural layer 300 and the substrate 500. The bonding layer 400 bonds the structural layer 300 to the substrate 500, and the bonding layer 400 is made of a metal material.

In an optional embodiment, a second electrode 700 is arranged on the second surface of the substrate 500. A material of the second electrode 700 may be, for example, Ti, Pt, Ni, Au, Au, Sn, etc.

In an optional embodiment, a third insulating layer 800 is arranged above a surface and a sidewall of the light-emitting diode mesa 201 and the structural layer 300 in the second region 520 except the discontinuous region 312. A material of the third insulating layer 800 may be a transparent insulating layer material to achieve insulating protection for the light-emitting diode device. Further, the third insulating layer 800 has a property of allowing most of the light to pass through, and the material of the third insulating layer 800 may be transparent organic silicone, epoxy resin, etc.

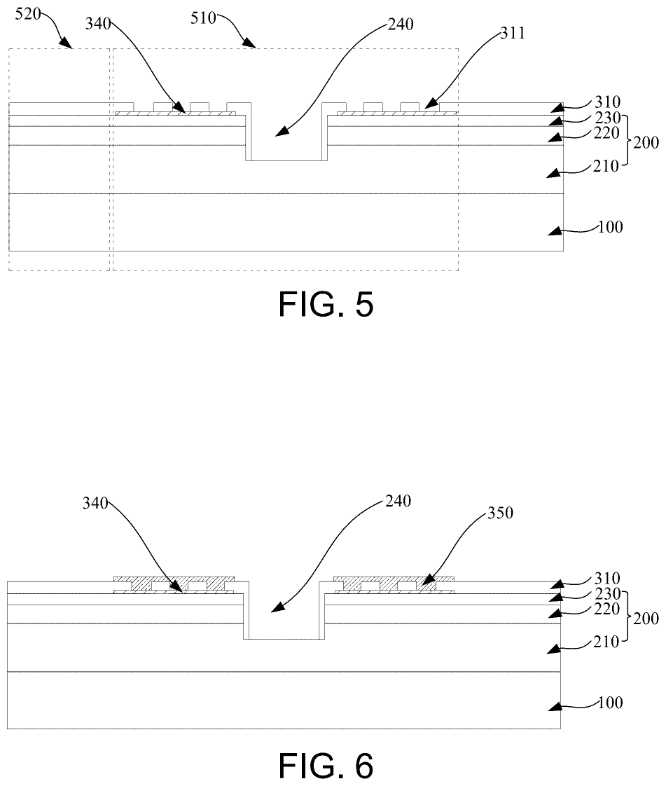

This embodiment also provides a method for preparing the light-emitting diode device. With reference to FIG. 3 to FIG. 12, the method for preparing the light-emitting diode device includes the following steps:

In S1, a growth substrate 100 is provided.

The growth substrate 100 is a growth substrate 100 for growing the semiconductor epitaxial layer 200 and may be a sapphire substrate, a silicon nitride substrate, a silicon substrate, a gallium nitride substrate, or an aluminum nitride substrate.

In S2, as shown in FIG. 3, the first semiconductor layer 210, the active layer 220, and the second semiconductor layer 230 are sequentially grown on the growth substrate 100 to form the semiconductor epitaxial layer 200. The semiconductor epitaxial layer 200 includes the first region 510 and the second region 520 surrounding the first region 510. It can be understood that the first region 510 and the second region 520 are three-dimensional space regions, and the first region 510 and the second region 520 may extend in a direction perpendicular to the semiconductor epitaxial layer 200.

The first semiconductor layer 210 is an N-type semiconductor layer, the active layer 220 is a multi-quantum well layer, and the second semiconductor layer 230 is a P-type semiconductor layer.

In S3, the structural layer 300 is formed on one side of the second semiconductor layer 230 of the semiconductor epitaxial layer 200, and the structural layer 300 includes the first insulating layer 310, the second insulating layer 320, and the electrode layer 330 stacked in sequence.

In an optional embodiment, step S3 specifically includes the following steps:

In S31, as shown in FIG. 4, a trench 240 is etched in the first region 510 of the semiconductor epitaxial layer 200, and the trench 240 penetrates the second semiconductor layer 230, the active layer 220, and a portion of the first semiconductor layer 210.

In S32, as shown in FIG. 5, the transparent conductive layer 340 is formed on the second semiconductor layer 230 at a periphery of the trench 240, the transparent conductive layer 340 is formed in the first region 510, and a periphery of the transparent conductive layer 340 is the second region 520.

The first insulating layer 310 is formed above a sidewall of the trench 240, the transparent conductive layer 340, and the second semiconductor layer 230 in the second region 520. A portion of the first insulating layer 310 in the first region 510 except the trench 240 is etched until the transparent conductive layer 340 is exposed, and at least one through hole 311 is thereby formed.

In S33, as shown in FIG. 6, the reflective metal layer 350 is formed on the first insulating layer 310 at the periphery of the trench 240 in the corresponding first region 510, and the reflective metal layer 350 also fills the through hole 311 and is connected to the transparent conductive layer 340.

In S34, as shown in FIG. 7, the current spreading layer 360 is formed on the reflective metal layer 350 and extends to a portion of the second region 520, and the region corresponding to the current spreading layer 360 in the second region 520 is the electrode region 522.

In S35, as shown in FIG. 8, the second insulating layer 320 covers the first insulating layer 310 on the sidewall of the trench 240 and is formed above the current spreading layer 360 and the first insulating layer 310 in the second region 520.

The electrode layer 330 is formed on the second insulating layer 320, covers the second insulating layer 320 on the sidewall of the trench 240, and is formed at a bottom portion of the trench 240, so that the electrical connection between the electrode layer 330 and the first semiconductor layer 210 is achieved.

In S36, as shown in FIG. 9, the bonding layer 400 is formed on the electrode layer 330, covers the electrode layer 330 of the trench 240, and fills the trench 240, and the conductive pillar 241 is formed in the trench 240.

In S4, the substrate 500 is provided, and the substrate 500 is bonded to the structural layer 300.

In an optional embodiment, the substrate 500 has the first surface and the second surface arranged opposite each other. After the preparation process shown in FIG. 4 to FIG. 9, the first surface of the substrate 500 is bonded to the electrode layer 330 of the structural layer 300 via the bonding layer 400.

In S5, as shown in FIG. 10, the growth substrate 100 is removed to expose the first semiconductor layer 210.

In S6, as shown in FIG. 11, the semiconductor epitaxial layer 200 is etched on the first semiconductor layer 210, and the etching stops on the surface of the first insulating layer 310. The unetched semiconductor epitaxial layer 200 forms the light-emitting diode mesa 201. The region corresponding to the light-emitting diode mesa 201 is the first region 510, and the region corresponding to the etched semiconductor epitaxial layer 200 is the second region 520.

In an optional embodiment, as shown in FIG. 11, the surface of the first semiconductor layer 210 of the light-emitting diode mesa 201 away from the active layer 220 is roughened.

In S7, as shown in FIG. 12, the first insulating layer 310 in the electrode region 522 is etched until the current spreading layer 360 is exposed, and the discontinuity region 312 is formed. As shown in FIG. 13, the first electrode 600 is formed in the discontinuous region 312, and the first electrode 600 is connected to the current spreading layer 360.

In S8, as shown in FIG. 2, the third insulating layer 800 is formed on the surface and the sidewall of the light-emitting diode mesa 201 and the surface of the first insulating layer 310 in the second region 520 except for the discontinuous region 312. The second electrode 700 is formed on the second surface of the substrate 500.

### Embodiment 2

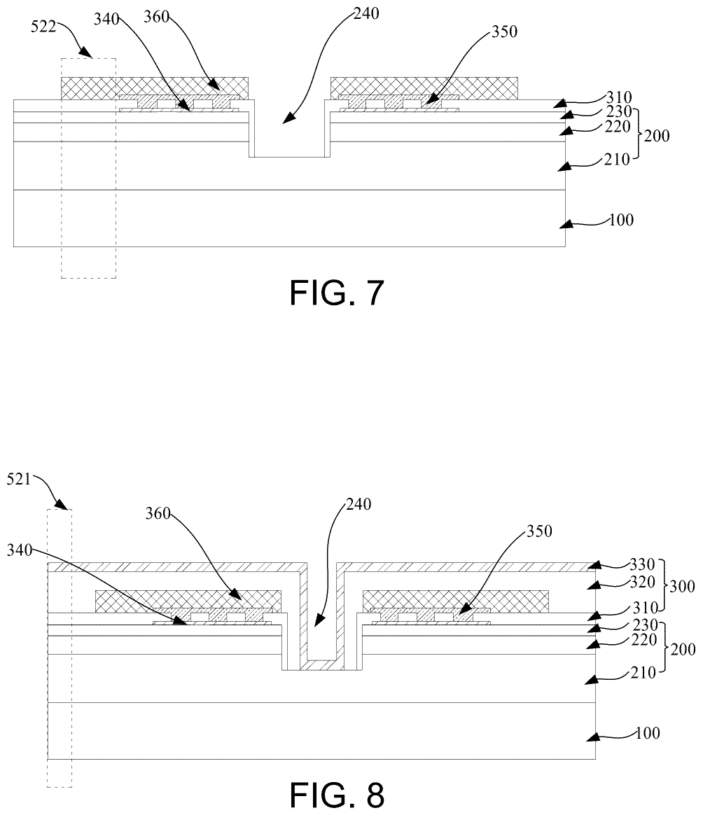

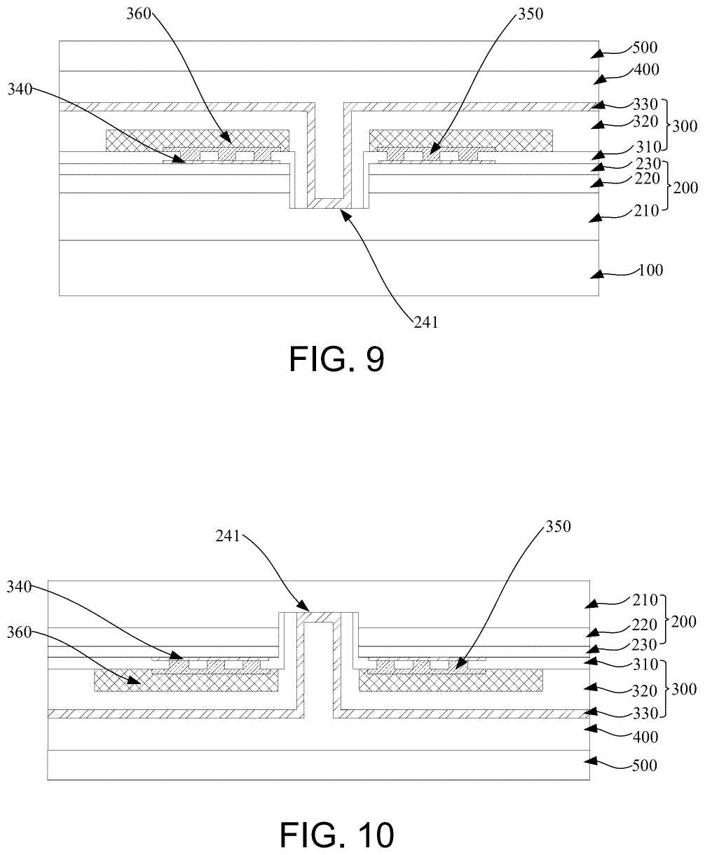

This embodiment provides a light-emitting diode device as well. As shown in FIG. 14 and FIG. 15, the light-emitting diode device provided in this embodiment also includes the substrate 500, the structural layer 300, and the light-emitting diode mesa 201. The substrate 500 has the first surface and the second surface arranged opposite each other. The first surface includes the first region 510 and the second region 520, and the second region 520 surrounds the first region 510. The structural layer 300 covers the first region 510 and the second region 520 and at least includes the electrode layer 330, the second insulating layer 320, and the first insulating layer 310 stacked in sequence from the first surface. The light-emitting diode mesa 201 is arranged above the structural layer 300, corresponds to the first region 510, and includes the semiconductor epitaxial layer 200 including the second semiconductor layer 230, the active layer 220, and the first semiconductor layer 210 stacked in sequence from the first surface. The difference from Embodiment 1 is that:

As shown in FIG. 15, the second region 520 further includes a middle region 523 located between the edge region 521 and the electrode region 522, and a thickness of the first insulating layer 310 located in the edge region 521 is less than a thickness of the first insulating layer 310 located in the middle region 523. Thinning the thickness of the first insulating layer 310 in the edge region 521 is beneficial to further reducing the total thickness of the first insulating layer 310 and the second insulating layer 320 in the edge region 521, making laser scribing easier. In this way, the cutting difficulty is further lowered, the scribing deviation is reduced, and the appearance yield of the light-emitting diode device formed by cutting is improved. Since the second insulating layer 320 has the function of protecting the interior of the light-emitting diode device, thinning the first insulating layer 310 can reduce the difficulty of cutting and prevent the second insulating layer 320 from cracking during cutting. In this way, the leakage risk of the light-emitting diode device is reduced, and the quality of the light-emitting diode device is further improved.

In an optional embodiment, the third insulating layer 800 is arranged above the surface and the sidewall of the light-emitting diode mesa 201 and the structural layer 300 in the second region 520 except the discontinuous region 312 and the edge region 521. The third insulating layer 800 implements insulation protection for the light-emitting diode device, and further, the third insulating layer 800 has a property of allowing most of the light to pass through. The material of the third insulating layer 800 may be transparent organic silicone, epoxy resin, etc.

The method for preparing the light-emitting diode device provided in this embodiment also includes steps S1 to S7 provided in Embodiment 1, and is different from Embodiment 1 in that:

As shown in FIG. 15, in step S8, when the third insulating layer 800 is arranged above the surface and the sidewall of the light-emitting diode mesa 201 and the structural layer 300 in the second region 520 except the discontinuous region 312 and the edge region 521, the first insulating layer 310 in the edge region 521 is etched simultaneously. It should be noted that when etching the first insulating layer 310 in the edge region 521, the second insulating layer 320 cannot be exposed. The second insulating layer 320 exhibits the function of protecting the internal structure, and if the second insulating layer 320 is exposed, there is a risk of electrical leakage. The second electrode 700 is formed on the second surface of the substrate 500 in step S8 as well.

### Embodiment 3

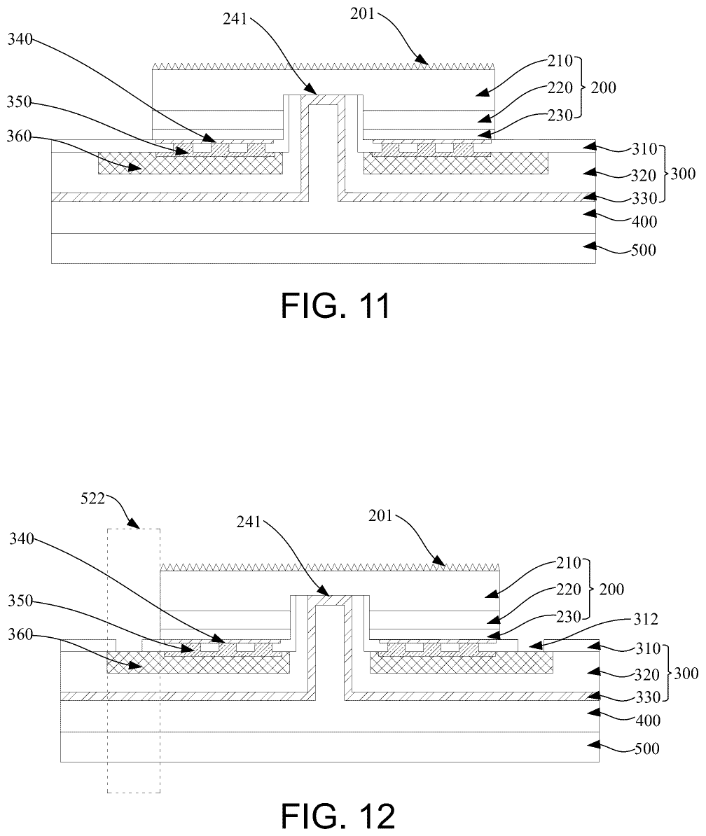

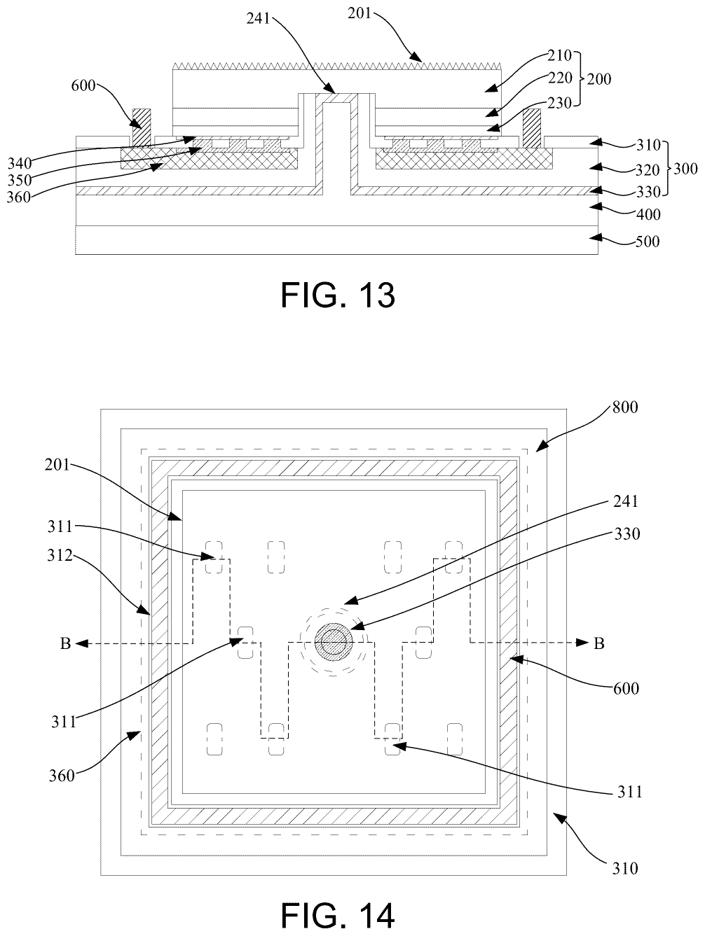

This embodiment provides a light-emitting diode device as well. As shown in FIG. 16 and FIG. 17, the light-emitting diode device provided in this embodiment also includes the substrate 500, the structural layer 300, and the light-emitting diode mesa 201. The substrate 500 has the first surface and the second surface arranged opposite each other. The first surface includes the first region 510 and the second region 520, and the second region 520 surrounds the first region 510. The structural layer 300 covers the first region 510 and the second region 520 and at least includes the electrode layer 330, the second insulating layer 320, and the first insulating layer 310 stacked in sequence from the first surface. The light-emitting diode mesa 201 is arranged above the structural layer 300, corresponds to the first region 510, and includes the semiconductor epitaxial layer 200 including the second semiconductor layer 230, the active layer 220, and the first semiconductor layer 210 stacked in sequence from the first surface. The difference between Embodiment 1 and Embodiment 2 lies in that:

As shown in FIG. 17, the structural layer 300 located in the edge region 521 at least includes the electrode layer 330 and the second insulating layer 320 stacked in sequence from the first surface, and a metal blocking wall 370 is arranged above the second insulating layer 320. A material of the metal blocking wall 370 may be, for example, Ti, Pt, Ni, Au, etc. The metal blocking wall 370 in the edge region 521 replaces the first insulating layer 310. When cutting the light-emitting diode device, the metal blocking wall 370 facilitates the laser transmission and can effectively prevent the second insulating layer 320 from being cut and cracked, thereby reducing the difficulty of cutting. Further, the metal blocking wall 370 also exhibits the function of blocking slag, so that the appearance yield of the light-emitting diode device formed by cutting is further improved, and the quality of the light-emitting diode device is further enhanced.

In an optional embodiment, a height of the metal blocking wall 370 is between 1 μm and 2 μm. To be specific, for example, the height of the metal blocking wall 370 may be 1 μm, 1.2 μm, 1.4 μm, 1.6 μm, 1.8 μm, 2 μm, etc.

In an optional embodiment, the third insulating layer 800 is arranged above the surface and the sidewall of the light-emitting diode mesa 201, a sidewall close to the light-emitting diode mesa 201 and a surface of the metal blocking wall 370, and the structural layer 300 in the electrode region 522 except the discontinuous region 312. The third insulating layer 800 has a property of allowing most of the light to pass through, and the material of the third insulating layer 800 may be transparent organic silicone, epoxy resin, etc. Further, the third insulating layer 800 has the function of insulating and protecting the light-emitting diode device.

The method for preparing the light-emitting diode device provided in this embodiment also includes steps S1 to S6 provided in Embodiment 1 or Embodiment 2, and is different from Embodiment 1 and Embodiment 2 in that:

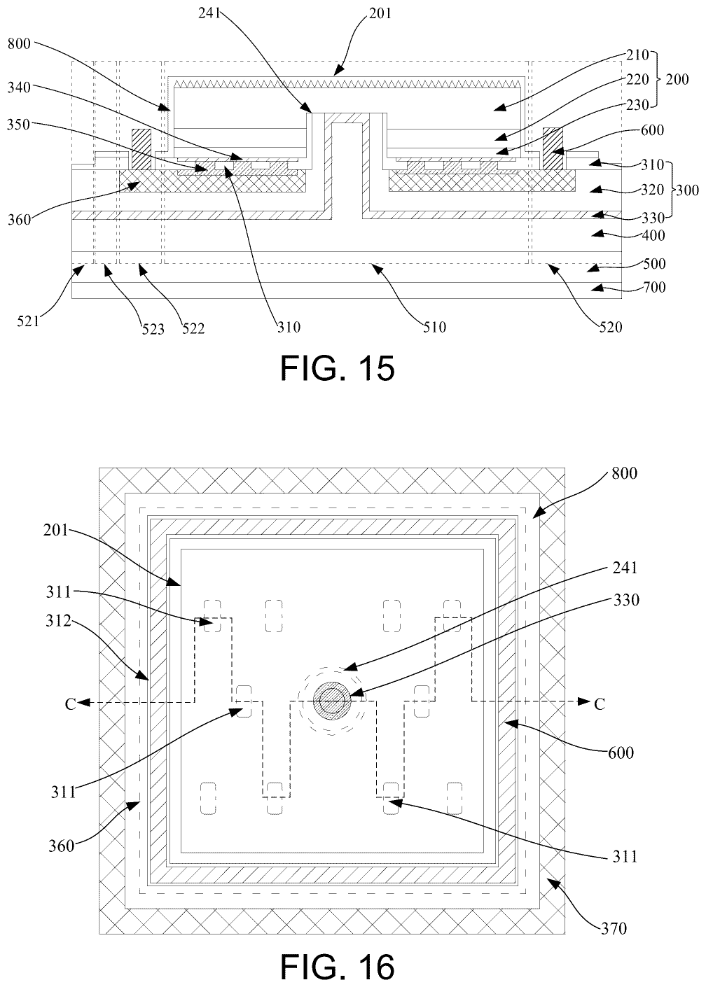

As shown in FIG. 18, in step S7, the first insulating layer 310 in the electrode region 522 is etched until the current spreading layer 360 is exposed, and the discontinuity region 312 is formed. The first insulating layer 310 in the edge region 521 is simultaneously etched until the second insulating layer 320 is exposed to form a metal blocking wall region 313 corresponding to the edge region 521. As shown in FIG. 19, when the first electrode 600 is formed in the discontinuous region 312, the metal blocking wall 370 is simultaneously formed in the metal blocking wall region 313. Optionally, the height of the metal blocking wall 370 is between 1 μm and 2 μm. To be specific, for example, the height of the metal blocking wall 370 may be 1 μm, 1.2 μm, 1.4 μm, 1.6 μm, 1.8 μm, 2 μm, etc.

As shown in FIG. 17, in step S8, the third insulating layer 800 is arranged above the surface and the sidewall of the light-emitting diode mesa 201, the sidewall close to the light-emitting diode mesa 201 and the surface of the metal blocking wall 370, and the structural layer 300 in the electrode region 522 except the discontinuous region 312. The second electrode 700 is formed on the second surface of the substrate 500 in step S8 as well.

### Embodiment 4

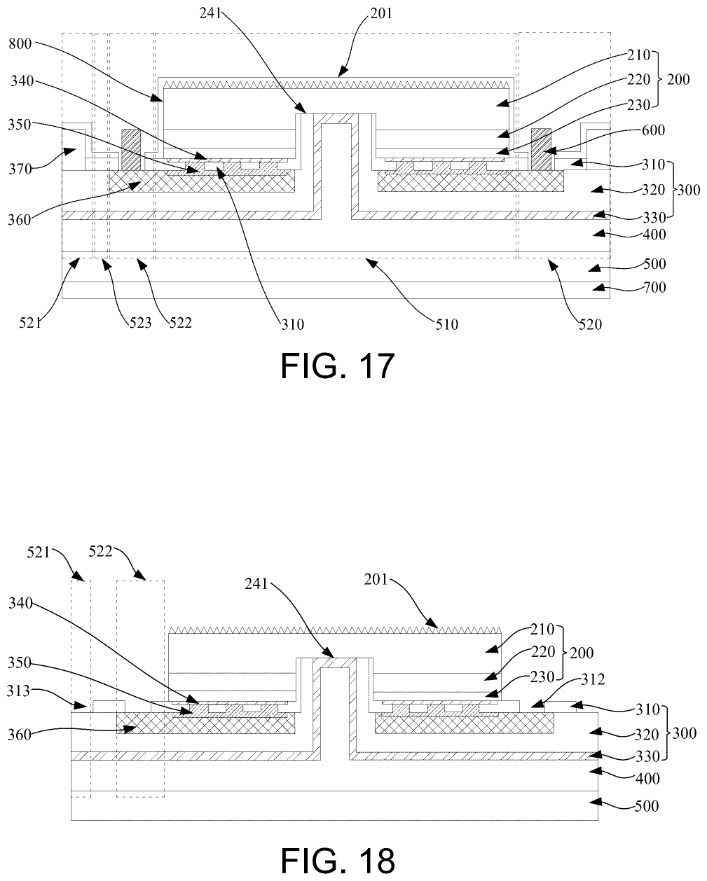

This embodiment provides a wafer structure. As shown in FIG. 20, the wafer structure in this embodiment includes a plurality of sequentially arranged light-emitting diode devices, the light-emitting diode devices may be the light-emitting diode devices provided in Embodiment 1, and edges of the second regions 520 of adjacent light-emitting diode devices are connected to each other to form a cutting path 900.

In this embodiment, the cutting path 900 of the wafer structure is located in the edge region 521 of the second region 520 of the light-emitting diode device provided in the Embodiment 1. When the wafer structure is cut along the cutting path 900, since the first insulating layer 310 and the second insulating layer 320 in the structural layer 300 of the cutting path 900 are CVD film layers, the refractive index of the CVD film layer is lower than that of the epitaxial layer, so the laser can easily penetrate and scribe it, and the cutting difficulty is reduced. In this way, the scribing deviation can be reduced, the cracking and damaging are decreased, the appearance yield of the light-emitting diode device formed by cutting is effectively improved, and the quality of the light-emitting diode device is enhanced.

### Embodiment 5

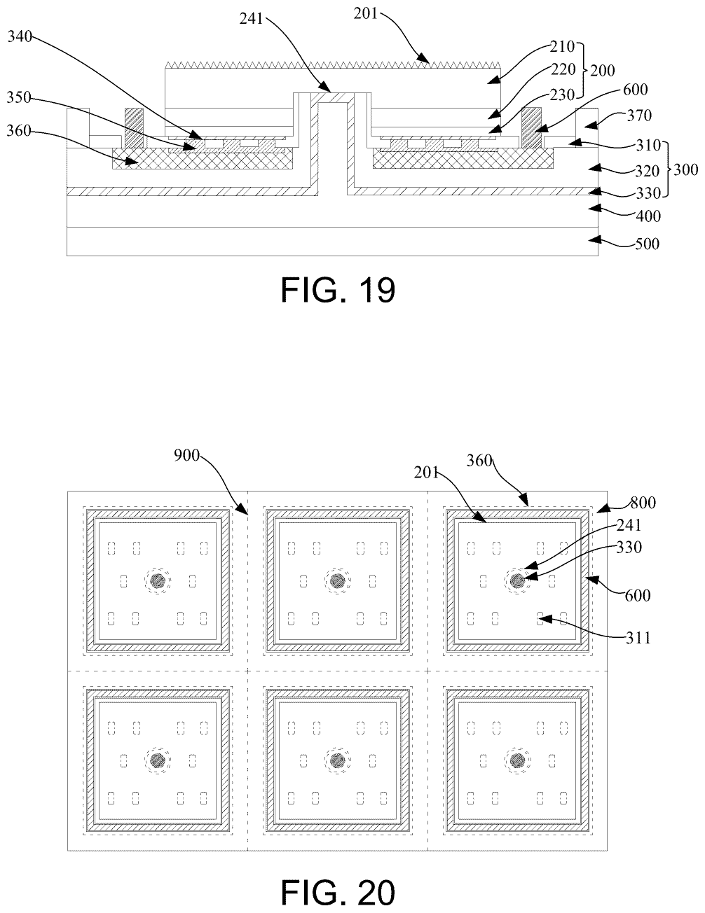

This embodiment provides a wafer structure as well. As shown in FIG. 21, the wafer structure in this embodiment includes a plurality of light-emitting diode devices arranged in sequence as well, and edges of the second regions 520 of adjacent light-emitting diode devices are connected to each other to form the cutting path 900. The difference from Embodiment 4 is that:

As shown in FIG. 21, the light-emitting diode device may be the light-emitting diode device provided in Embodiment 2. The cutting path 900 is located in the edge region 521 of the second region 520 of the light-emitting diode device provided in the Embodiment 2. The thickness of the first insulating layer 310 in the edge region 521 is less than the thickness of the first insulating layer 310 in the middle region 523. Thinning the thickness of the first insulating layer 310 in the edge region 521 is beneficial to further reducing the total thickness of the first insulating layer 310 and the second insulating layer 320 in the edge region 521, making it easier to scribe the cutting path 900 during laser cutting. The cutting difficulty is further reduced, the second insulating layer 320 is prevented from being cracked during cutting, so the appearance yield of the light-emitting diode device formed by cutting is further improved, and the quality of the light-emitting diode device is further enhanced.

### Embodiment 6

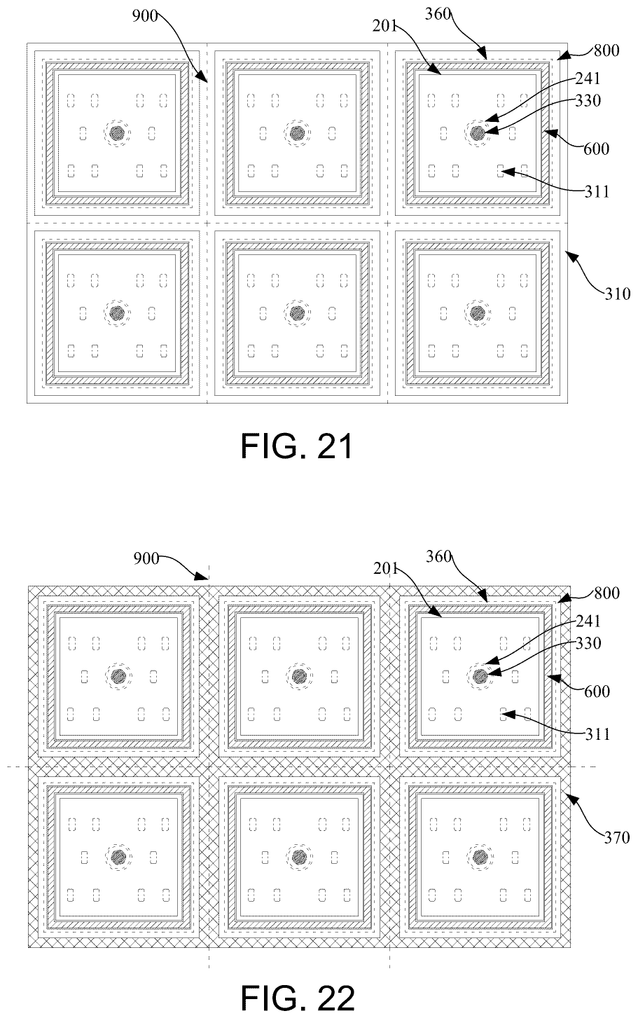

This embodiment provides a wafer structure as well. As shown in FIG. 22, the wafer structure in this embodiment includes a plurality of light-emitting diode devices arranged in sequence as well, and edges of the second regions 520 of adjacent light-emitting diode devices are connected to each other to form the cutting path 900. The difference from Embodiment 3 or Embodiment 4 is that:

As shown in FIG. 22, the light-emitting diode device may be the light-emitting diode device provided in Embodiment 3, and the cutting path 900 is located in the edge region 521 of the second region 520 of the light-emitting diode device provided in the Embodiment 3. The structural layer 300 located in the edge region 521 at least includes the electrode layer 330 and the second insulating layer 320 stacked in sequence from the first surface, and the metal blocking wall 370 is arranged above the second insulating layer 320. The material of the metal blocking wall 370 may be, for example, Ti, Pt, Ni, Au, etc. The metal blocking wall 370 in the edge region 521 replaces the first insulating layer 310. When cutting the wafer structure, the metal blocking wall 370 located at the cutting path 900 facilitates the laser transmission and can effectively prevent the second insulating layer 320 from being cut and cracked, thereby reducing the difficulty of cutting. Further, the metal blocking wall 370 also exhibits the function of blocking slag, so that the appearance yield of the light-emitting diode device formed by cutting is further improved, and the quality of the light-emitting diode device is further enhanced.

The above-mentioned embodiments only illustrate the principles and effects of the disclosure, but are not intended to limit the disclosure. A person having ordinary skill in the art can modify or change the abovementioned embodiments without departing from the spirit and scope of the disclosure. Therefore, all equivalent modifications or changes made by a person having ordinary skill in the art without departing from the spirit and technical ideas disclosed in the disclosure shall still be covered by the claims of the disclosure.

What is claimed is:

1. A light-emitting diode device, comprising:
a substrate having a first surface and a second surface arranged opposite to each other, wherein the first surface comprises a first region and a second region, and the second region surrounds the first region;
a structural layer covering the first region and the second region and at least comprising an electrode layer, a second insulating layer, and a first insulating layer stacked in sequence from the first surface; and
a light-emitting diode mesa arranged above the first region of the structural layer and comprising a semiconductor epitaxial layer comprising a second semiconductor layer, an active layer, and a first semiconductor layer stacked in sequence from the first surface.

2. The light-emitting diode device according to claim 1, wherein the second region comprises an edge region away from the first region, and a thickness of the first insulating layer located in the edge region is between 0.1 μm and 1.4 μm.

3. The light-emitting diode device according to claim 2, wherein a total thickness of the first insulating layer and the second insulating layer located in the edge region is between 0.4 μm and 5 μm.

4. The light-emitting diode device according to claim 3, wherein the second region further comprises an electrode region located between the edge region and the first region, wherein the first insulating layer located in the electrode region has a discontinuous region, and a first electrode is arranged in the discontinuous region.

5. The light-emitting diode device according to claim 4, wherein the second region further comprises a middle region located between the edge region and the electrode region, and a thickness of the first insulating layer located in the edge region is less than a thickness of the first insulating layer located in the middle region.

6. The light-emitting diode device according to claim 4, wherein the structural layer located in the edge region at least comprises the electrode layer and the second insulating layer stacked in sequence from the first surface, and a metal blocking wall is arranged above the second insulating layer.

7. The light-emitting diode device according to claim 6, wherein a height of the metal blocking wall is between 1 μm and 2 μm.

8. The light-emitting diode device according to claim 4, wherein a width of the first electrode is less than a width of the discontinuous region.

9. The light-emitting diode device according to claim 8, wherein the width of the discontinuous region is between 2 μm and 4 μm.

10. The light-emitting diode device according to claim 4, wherein a current spreading layer is arranged between the first insulating layer and the second insulating layer and extends from the first region to the electrode region, and the first electrode is connected to the current spreading layer.

11. The light-emitting diode device according to claim 10, wherein a thickness of the current spreading layer is between 0.3 μm and 1 μm.

12. The light-emitting diode device according to claim 4, wherein a third insulating layer is arranged above a surface and a sidewall of the light-emitting diode mesa and the structural layer in the second region except the discontinuous region.

13. The light-emitting diode device according to claim 5, wherein a third insulating layer is arranged above a surface and a sidewall of the light-emitting diode mesa and the structural layer in the second region except the discontinuous region and the edge region.

14. The light-emitting diode device according to claim 6, wherein a third insulating layer is arranged above a surface and a sidewall of the light-emitting diode mesa, a sidewall close to the light-emitting diode mesa and a surface of the metal blocking wall, and the structural layer in the electrode region except the discontinuous region.

15. The light-emitting diode device according to claim 12, wherein the first insulating layer, the second insulating layer, and the third insulating layer are all transparent insulating layers.

16. The light-emitting diode device according to claim 10, wherein in a region corresponding to the light-emitting diode mesa, a through hole is arranged in the first insulating layer, and a reflective metal layer is arranged between the first insulating layer and the current spreading layer, the reflective metal layer covers the first insulating layer at the light-emitting diode mesa and fills the through hole to be electrically connected to the second semiconductor layer, and
a transparent conductive layer is further arranged between the first insulating layer and the second semiconductor layer at the light-emitting diode mesa.

17. The light-emitting diode device according to claim 1, wherein the light-emitting diode mesa further comprises a conductive pillar arranged on the semiconductor epitaxial layer, the conductive pillar penetrates the second semiconductor layer, the active layer, and a portion of the first semiconductor layer, a sidewall of the conductive pillar is the first insulating layer and the second insulating layer arranged in sequence, and the electrode layer is formed on a sidewall of the second insulating layer and the first semiconductor layer to be electrically connected to the first semiconductor layer.

18. The light-emitting diode device according to claim 1, wherein a bonding layer is further arranged between the structural layer and the substrate, and
a second electrode layer is arranged on the second surface.

19. A wafer structure comprising a plurality of light-emitting diode devices according to claim 1 arranged in sequence, wherein edges of the second regions of adjacent light-emitting diode devices are connected to each other to form a cutting path.
